(19) United States
(12) Patent Application Publication
(10) Pub. No.: US 2025/0069886 A1
(43) Pub. Date: Feb. 27, 2025

(54) THIN FILM MANUFACTURING METHOD AND THIN FILM

(71) Applicant: JUSUNG ENGINEERING CO., LTD., Gwangju-si, Gyeonggi-do (KR)

(72) Inventors: Duck Ho KIM, Gwangju-si, Gyeonggi-do (KR); Min Hyuk KIM, Gwangju-si, Gyeonggi-do (KR); Kyung In MIN, Gwangju-si, Gyeonggi-do (KR); Chang Kyun PARK, Gwangju-si, Gyeonggi-do (KR); Jun Hee HAN, Gwangju-si, Gyeonggi-do (KR)

(21) Appl. No.: 18/726,391

(22) PCT Filed: Jan. 25, 2023
(86) PCT No.: PCT/KR2023/001094

§ 371 Date: Jul. 2, 2024

(30) Foreign Application Priority Data
Jan. 27, 2022 (KR) 10-2022-0011893
Jan. 19, 2023 (KR) 10-2023-0008137

(51) Int. Cl. H01L 21/02; C23C 16/40; H01L 29/49; H01L 29/51

(52) U.S. Cl. CPC H01L 21/0234; C23C 16/405; H01L 21/02181; H01L 21/02189; H01L 29/4908; H01L 29/517

(57) ABSTRACT

The present inventive concept relates to a thin film manufacturing method and a thin film. The thin film manufacturing method comprises: an adsorption step of adsorbing a high-k material on a substrate by spraying a source gas consisting of a high-k material; a deposition step of depositing a thin film consisting of the high-k material on the substrate by spraying a reaction gas that reacts with the source gas; and a crystallization step of crystallizing the high-k material using plasma.

### TECHNICAL FIELD

The present inventive concept relates to a thin film manufacturing method of manufacturing a thin film on a substrate through a processing process such as a deposition process on the substrate.

### BACKGROUND ART

Generally, a thin-film layer, a thin-film circuit pattern, or an optical pattern should be formed on a substrate for manufacturing a semiconductor device, a display device, a solar cell, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Through such a processing process on a substrate, a thin film may be manufactured on the substrate.

Recently, a semiconductor device, a display device, and a solar cell have been more miniaturized and have also been developed to have a thinner thickness, and to this end, a thickness of a thin film should be thinned. However, in a thin film which is implemented as an insulation layer between a semiconductor layer and a gate layer in a thin film transistor (TFT), there is a problem where the leakage of a current occurs due to a tunneling phenomenon as a thickness of the thin film is thinned.

Therefore, it is required to develop a thin film for reducing the leakage of a current despite that a thickness of the thin film is implemented to be thin.

### DISCLOSURE

### Technical Problem

The present inventive concept is devised to solve the above-described problem and is for providing a method of manufacturing a thin film and a thin film, which may reduce the leakage of a current despite having a thin thickness.

### Technical Solution

To accomplish the above-described objects, the present inventive concept may include the following elements.

A method of manufacturing a thin film according to the present inventive concept may include: an adsorption step of injecting a source gas including a high-k dielectric material to adsorb the high-k dielectric material onto a substrate; a deposition step of injecting a reactant gas reacting on the source gas to deposit a thin film including the high-k dielectric material on the substrate; and a crystallization step of crystallizing the high-k dielectric material by using plasma.

A thin film according to the present inventive concept may include a thin film layer formed on a substrate by using a mixed material including a high-k dielectric material. The thin film layer may be formed to have a thickness of 40 Å to 70 Å and may be crystallized to have a dielectric constant of 20 K to 30 K.

### Advantageous Effect

According to the present inventive concept, the following effects may be realized.

The present inventive concept may be implemented so that a thin film is formed of a high-k dielectric material and is crystallized by using plasma, and thus, may more decrease the leakage of a current despite being formed to have a thinner thickness. Accordingly, the present inventive concept may contribute to manufacture a thin film transistor which is finer and has a thinner thickness.

The present inventive concept may be implemented so that a thin film is formed of a high-k dielectric material and is crystallized by using plasma. Accordingly, the present inventive concept may manufacture a thin film having more enhanced quality through film densification, crystallization, and impurity removal.

### DESCRIPTION OF DRAWINGS

FIG. 1 is a schematic block diagram illustrating an example of a substrate processing apparatus which performs a method of manufacturing a thin film according to the present inventive concept.

FIG. 2 is a schematic side cross-sectional view of an injection unit injecting a gas in an example of a substrate processing apparatus which performs a method of manufacturing a thin film according to the present inventive concept.

FIG. 3 is a schematic side cross-sectional view illustrating an example of a thin film transistor.

FIGS. 4 to 7 are schematic flowcharts of a method of manufacturing a thin film according to the present inventive concept.

### MODE FOR INVENTIVE CONCEPT

Hereinafter, an embodiment of a method of manufacturing a thin film according to the present inventive concept will be described in detail with reference to the accompanying drawings. In describing an embodiment of the present inventive concept, when an arbitrary structure is described as being formed “on” or “under” another structure, this description should be construed as including a case, where a third structure is disposed between the structures, as well as a case where the structures contact each other.

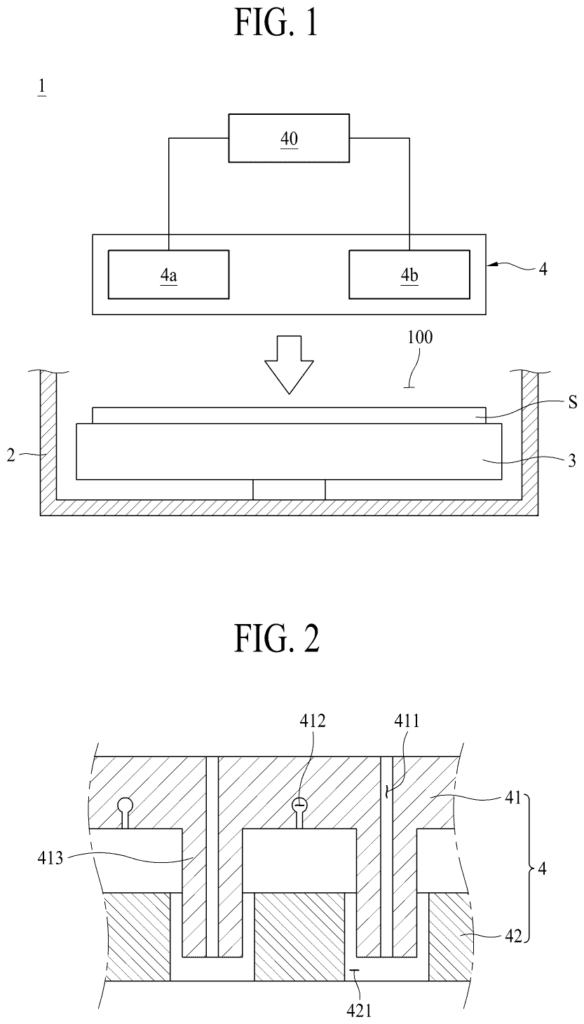

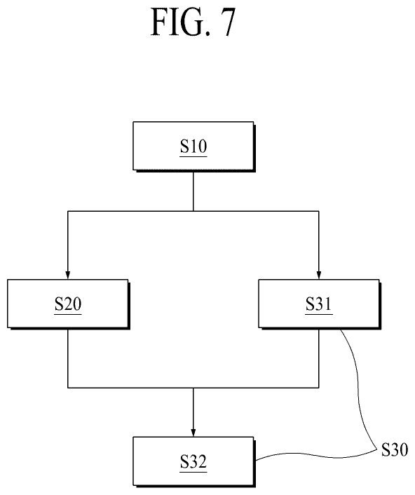

Referring to FIGS. 1 to 4, the method of manufacturing a thin film according to the present inventive concept performs a processing process on a substrate S to manufacture a thin film on the substrate S. The substrate S may be a silicon substrate, a glass substrate, a metal substrate, or the like.

The method of manufacturing a thin film according to the present inventive concept may be performed by a substrate processing apparatus 1. Before describing an embodiment of the method of manufacturing a thin film according to the present inventive concept, the substrate processing apparatus 1 will be described below in detail.

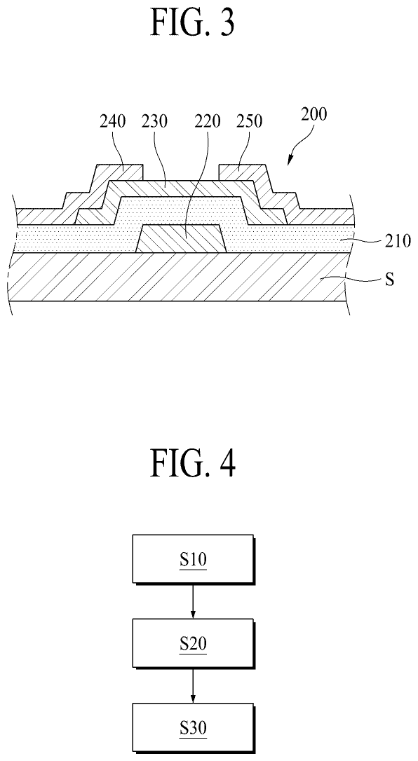

Referring to FIGS. 1 and 2, the substrate processing apparatus 1 may include a chamber 2, a substrate supporting unit 3, and an injection unit 4.

The chamber 2 provides a processing space 100. A process of performing a processing process on the substrate S to manufacture a thin film on the substrate S may be performed in the processing space 100. The processing space 100 may be disposed in the chamber 2. An exhaust port (not shown) which exhausts a gas from the processing space 100 may be coupled to the chamber 2. The substrate supporting unit 3 and the injection unit 4 may be disposed in the chamber 2.

The substrate supporting unit 3 supports the substrate S. The substrate supporting unit 3 may support one substrate S, or may support a plurality of substrates S. In a case where the plurality of substrates S are supported by the substrate supporting unit 3, a process of performing a processing process on the plurality of substrates S at a time to manufacture a thin film on each of the substrates S may be performed. The substrate supporting unit 3 may be coupled to the chamber 2. The substrate supporting unit 3 may be disposed in the chamber 2.

The injection unit 4 injects a gas toward the substrate supporting unit 3. The injection unit 4 may be connected with a gas storage unit 40. In this case, the injection unit 4 may inject a gas, supplied from the gas storage unit 40, toward the substrate supporting unit 3. The injection unit 4 may be disposed in the chamber 2. The injection unit 4 may be disposed to be opposite to the substrate supporting unit 3. The injection unit 4 may be disposed over the substrate supporting unit 3. The processing space 100 may be disposed between the injection unit 4 and the substrate supporting unit 3. The injection unit 4 may be coupled to a lid (not shown). The lid may be coupled to the chamber 2 to cover an upper portion of the chamber 2.

The injection unit 4 may include a first gas flow path 4a and a second gas flow path 4b.

The first gas flow path 4a is for injecting a first gas. The first gas flow path 4a may communicate with the processing space 100. One side of the first gas flow path 4a may be connected with the gas storage unit 40 through a pipe, a hose, or the like. The other side of the first gas flow path 4a may communicate with the processing space 100. Accordingly, the first gas supplied from the gas storage unit 40 may flow along the first gas flow path 4a, and then, may be injected into the processing space 100 through the first gas flow path 4a. The first gas flow path 4a may function as a flow path for enabling the first gas to flow and may function as an injection port for injecting the first gas into the processing space 100.

The second gas flow path 4b is for injecting a second gas. The second gas and the first gas may be different gases. For example, when the first gas is a source gas, the second gas may be a reactant gas. One side of the second gas flow path 4b may be connected with the gas storage unit 40 through a pipe, a hose, or the like. The other side of the second gas flow path 4b may communicate with the processing space 100. Accordingly, the second gas supplied from the gas storage unit 40 may flow along the second gas flow path 4b, and then, may be injected into the processing space 100 through the second gas flow path 4b. The second gas flow path 4b may function as a flow path for enabling the second gas to flow and may function as an injection port for injecting the second gas into the processing space 100.

The second gas flow path 4b and the first gas flow path 4a may be disposed to be spatially separated from each other. Therefore, the second gas supplied from the gas storage unit 40 to the second gas flow path 4b may be injected into the processing space 100 without passing through the first gas flow path 4a. The first gas supplied from the gas storage unit 40 to the first gas flow path 4a may be injected into the processing space 100 without passing through the second gas flow path 4b. The second gas flow path 4b and the first gas flow path 4a may inject a gas toward different portions of the processing space 100.

For example, the injection unit 4 may include a first plate 41 and a second plate 42.

The first plate 41 is disposed over the second plate 42. The first plate 41 and the second plate 42 may be disposed apart from each other. A plurality of first gas holes 411 may be formed in the first plate 41. Each of the first gas holes 411 may function as a path for enabling the first gas to flow. The first gas holes 411 may be included in the first gas flow path 4a. A plurality of second gas holes 412 may be formed in the second plate 42. Each of the second gas holes 412 may function as a path for enabling a gas to flow. The second gas holes 412 may be included in the second gas flow path 4b. A plurality of protrusion members 413 may be coupled to the first plate 41. The protrusion members 413 may protrude toward the second plate 42 from a lower surface of the first plate 41. Each of the first gas holes 411 may be formed to pass through the first plate 41 and the protrusion member 413.

A plurality of openings 421 may be formed in the second plate 42. The openings 421 may be formed to pass through the second plate 42. The openings 421 may be disposed at a position corresponding to each of the protrusion members 413. Therefore, as illustrated in FIG. 2, the protrusion members 413 may be formed by a length which enables the protrusion members 413 to be respectively inserted into the openings 421. Although not shown, the protrusion members 413 may be formed by a length which enables the protrusion members 413 to be respectively disposed on the openings 421. The protrusion members 413 may be formed by a length which protrudes downward from the second plate 42. The second gas holes 412 may be disposed to inject a gas toward an upper surface of the second plate 42.

The injection unit 4 may generate plasma by using the second plate 42 and the first plate 41. In this case, a plasma power such as radio frequency (RF) power may be applied to the first plate 41, and the second plate 42 may be grounded. The first plate 41 may be grounded, and the plasma power may be applied to the second plate 42.

The method of manufacturing a thin film according to the present inventive concept may be performed by using the substrate processing apparatus 1.

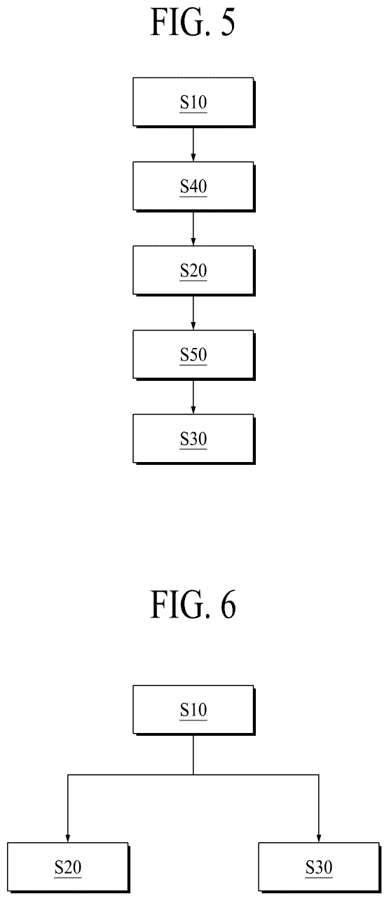

Referring to FIGS. 1 to 4, as illustrated in FIG. 3, the method of manufacturing a thin film according to the present inventive concept may manufacture a thin film implemented as an insulation layer 210 in a thin film transistor (TFT) 200. The insulation layer 210 may be disposed between a gate electrode 220 and a semiconductor layer 230. The gate electrode 220 may be formed on the substrate S. The semiconductor layer 230 may be formed on the insulation layer 210. A source electrode 240 and a drain electrode 250 may be formed on the semiconductor layer 230. When the thin film transistor 200 is manufactured to be more miniaturized and have a thinner thickness, the insulation layer 210 may be thinned, and the leakage of a current may occur due to a tunneling phenomenon as a thickness of the insulation layer 210 is thinned.

To decrease the leakage of a current, the method of manufacturing a thin film according to the present inventive concept is implemented to manufacture a thin film including a high-k dielectric material. Furthermore, the method of manufacturing a thin film according to the present inventive concept is implemented to manufacture a thin film by crystallizing a high-k dielectric material. Accordingly, the method of manufacturing a thin film according to the present inventive concept may manufacture a thin film for more reducing the leakage of a current, thereby contributing to manufacture the thin film transistor 200 which is finer and has a thinner thickness.

To this end, the method of manufacturing a thin film according to the present inventive concept may include an adsorption step S10, a deposition step S20, and a crystallization step S30.

The adsorption step S10 injects a source gas including a high-k dielectric material to adsorb the high-k dielectric material onto the substrate S. The adsorption step S10 may be performed by injecting the source gas onto the substrate S through the first gas flow path 4a included in the injection unit 4. The source gas may include at least one of hafnium (Hf) and zirconium (Zr). All of hafnium and zirconium correspond to a high-k dielectric material. The adsorption step S10 may be performed by injecting a mixed gas, including at least one of hafnium and zirconium as the source gas, onto the substrate S. In this case, a first source gas including hafnium and a second source gas including zirconium may be mixed with each other in a buffer tank disposed apart from the injection unit 4 to generate a mixed gas, and then, the mixed gas may be supplied to the injection unit 4 and may be injected into the processing space 100. Therefore, the method of manufacturing a thin film according to the present inventive concept may manufacture a thin film where a step coverage is enhanced, and moreover, may manufacture a thin film where the uniformity of a composition is enhanced. The adsorption step S10 may be performed by sequentially injecting the first source gas including hafnium and the second source gas including zirconium onto the substrate S. The source gas may include at least one of hafnium, zirconium, and aluminum (Al). For example, the source gas may be one of HfO₂, ZrO₂, AL₂O₃, and HfZrO.

The deposition step S20 injects a reactant gas reacting on the source gas to deposit a thin film including a high-k dielectric material on the substrate S. The deposition step S20 may be performed by injecting the reactant gas onto the substrate S through the second gas flow path 4b included in the injection unit 4. Through the adsorption step S10 and the deposition step S20, a thin film may be formed on the substrate S by an atomic layer deposition (ALD) process. The deposition step S20 may be performed by injecting ozone (O₃) as a reactant gas onto the substrate S.

The crystallization step S30 crystallizes a high-k dielectric material by using plasma. Because a thin film is manufactured by crystallizing a high-k dielectric material by using plasma through the crystallization step S30, the method of manufacturing a thin film according to the present inventive concept may realize the following effects.

First, with respect to the same thickness, in a comparative example which manufactures a thin film including a high-k dielectric material without the crystallization step S30, a leakage current value is greater than that of a thin film which is formed of a high-k dielectric material and is crystallized by the method of manufacturing a thin film according to the present inventive concept. Accordingly, the method of manufacturing a thin film according to the present inventive concept may be implemented to manufacture a thin film which is formed of a high-k dielectric material and is crystallized, and thus, may manufacture a thin film for more reducing the leakage of a current despite being formed to have a thickness which is thinner than that of a thin film according to the comparative example. Therefore, the method of manufacturing a thin film according to the present inventive concept may contribute to manufacture the thin film transistor 200 which is finer and has a thinner thickness.

Second, in a comparative example which crystallizes a high-k dielectric material through a thermal process, the high-k dielectric material is not crystallized when not formed to have a certain thickness or more. For example, a high-k dielectric material including at least one of hafnium and zirconium may be crystallized only when formed to have a thickness of 100 Å or more, through the thermal process. On the other hand, the method of manufacturing a thin film according to the present inventive concept is implemented to crystallize a high-k dielectric material by using plasma, and thus, may crystallize the high-k dielectric material despite being formed to have a thickness which is thinner than the comparative example which crystallizes the high-k dielectric material through the thermal process. For example, a high-k dielectric material including at least one of hafnium and zirconium may be crystallized only when formed to have a thickness of 60 Å or less, through the thermal process. Accordingly, the method of manufacturing a thin film according to the present inventive concept is implemented to crystallize a high-k dielectric material by using plasma, and thus, may manufacture a thin film for more reducing the leakage of a current despite being formed to have a thinner thickness.

Third, the method of manufacturing a thin film according to the present inventive concept may be implemented to form a thin film by using a high-k dielectric material and crystallize the thin film by using plasma, and thus, may realize a crystallization effect and a densification effect of increasing a density of a film. This is because, when plasma energy is transferred into the thin film by using plasma, impurities are removed while crystallization is being performed in the thin film, and only a crystal having a high bonding force remains as a crystal having a low bonding force is de-bonded. Accordingly, the method of manufacturing a thin film according to the present inventive concept may manufacture a thin film having more enhanced quality through film densification, crystallization, and impurity removal.

The crystallization step S30 may be performed by crystallizing a high-k dielectric material by using plasma in an ultra-high vacuum state. Accordingly, the method of manufacturing a thin film according to the present inventive concept may enhance the stability of a process in performing the crystallization step S30.

The crystallization step S30 may generate plasma by using a plasma gas including at least one of helium (He), argon (Ar), and ammonia (NH₃). In this case, the source gas may include at least one of hafnium and zirconium, and the reactant gas may be ozone. The source gas may include at least one of hafnium, zirconium, and aluminum (Al).

The crystallization step S30 may be performed after the deposition step S20 is performed. In this case, the method of manufacturing a thin film according to the present inventive concept may deposit a thin film on the substrate S through the adsorption step S10 and the deposition step S20, and then, may crystallize a high-k dielectric material of the thin film deposited on the substrate S by using plasma, through the crystallization step S30. After the crystallization step S30 is performed, and each step may be again performed from the adsorption step S10. Furthermore, in a case where the crystallization step S30 is performed after the deposition step S20 is performed, the method of manufacturing a thin film according to the present inventive concept may perform each step along with the thermal process. The thermal process may be continuously or intermittently performed while the adsorption step S10, the deposition step S20, and the crystallization step S30 are being performed.

Referring to FIGS. 1 to 5, the method of manufacturing a thin film according to the present inventive concept may include a first purge step S40 and a second purge step S50.

The first purge step S40 may be performed by injecting a purge gas onto the substrate S after the adsorption step S10 is performed. The first purge step S40 may be performed by injecting the purge gas onto the substrate S through at least one of the first gas flow path 4a and the second gas flow path 4b of the injection unit 4. The first purge step S40 may be performed by injecting the purge gas onto the substrate S through a purge gas flow path (not shown). The purge gas flow path, the first gas flow path 4a, and the second gas flow path 4b may be implemented to be spatially apart from one another. After the first purge step S40 is performed, the deposition step S20 may be performed.

The second purge step S50 may be performed by injecting the purge gas onto the substrate S after the deposition step S20 is performed. The second purge step S50 may be performed by injecting the purge gas onto the substrate S through at least one of the first gas flow path 4a and the second gas flow path 4b of the injection unit 4. The second purge step S50 may be performed by injecting the purge gas onto the substrate S through the purge gas flow path (not shown). After the second purge step S50 is performed, the crystallization step S30 may be performed.

Referring to FIGS. 1 to 6, in the method of manufacturing a thin film according to the present inventive concept, the deposition step S20 and the crystallization step S30 may be performed together. In this case, a reactant gas injected onto the substrate S through the deposition step S20 may be activated by using plasma generated by the crystallization step S30 and may reach the substrate S. Accordingly, because the deposition step S20 and the crystallization step S30 are performed together, the method of manufacturing a thin film according to the present inventive concept may deposit a thin film including a high-k dielectric material onto the substrate S and may crystallize the high-k dielectric material by using plasma. After the deposition step S20 and the crystallization step S30 are performed together, each step may be again performed from the adsorption step S10.

Referring to FIGS. 1 to 7, in the method of manufacturing a thin film according to the present inventive concept, the crystallization step S30 may include a first crystallization step S31 and a second crystallization step S32.

The first crystallization step S31 crystallizes the high-k dielectric material by using plasma. The first crystallization step S31 may be performed along the deposition step S20. In this case, the reactant gas injected onto the substrate S through the deposition step S20 may be activated by using plasma generated by the first crystallization step S31 and may reach the substrate S. Accordingly, because the deposition step S20 and the first crystallization step S31 are performed together, the method of manufacturing a thin film according to the present inventive concept may deposit the thin film including the high-k dielectric material onto the substrate S and may crystallize the high-k dielectric material by using plasma.

The second crystallization step S32 crystallizes the high-k dielectric material by using plasma. After the deposition step S20 and the first crystallization step S31 are performed, the second crystallization step S32 may be performed. Therefore, the method of manufacturing a thin film according to the present inventive concept may be implemented to primarily crystallize the thin film through the first crystallization step S31 and then secondarily crystallize the thin film through the second crystallization step S32. Therefore, the method of manufacturing a thin film according to the present inventive concept may increase a crystallization rate of a thin film, and thus, may manufacture a thin film for more reducing the leakage of a current despite being formed to have a thinner thickness. Accordingly, the method of manufacturing a thin film according to the present inventive concept may contribute to manufacture the thin film transistor 200 which is finer and has a thinner thickness. After the second crystallization step S32 is performed, each step may be again performed from the adsorption step S10.

Hereinafter, an embodiment of a thin film according to the present inventive concept will be described in detail.

Referring to FIGS. 1 to 7, the thin film according to the present inventive concept may be manufactured by the method of manufacturing a thin film according to the present inventive concept described above. The thin film according to the present inventive concept may be implemented as the insulation layer 210 disposed between the gate electrode 220 and the semiconductor layer 230, in the thin film transistor 200.

The thin film according to the present inventive concept may include a thin film layer which is formed on the substrate S. The thin film layer may be formed on the substrate S by using a mixed material including a high-k dielectric material. The thin film layer may be formed to have a thickness of 40 Å to 70 Å and may be crystallized to have a dielectric constant of 20 K to 30 K. Accordingly, the thin film according to the present inventive concept may be formed to have a thin thickness and may be implemented to have a dielectric constant for decreasing the leakage of a current, and thus, may contribute to manufacture the thin film transistor 200 which is finer and has a thinner thickness.

Here, when the thin film layer is formed to have a thickness of less than 40 Å, the leakage of a current increases, and when the thin film layer is formed to have a thickness of more than 70 Å, it is difficult to miniaturize a thickness of the thin film layer. When the thin film layer is crystallized to have a dielectric constant of less than 20 K, it is difficult to decrease the leakage of a current, and when the thin film layer is crystallized to have a dielectric constant of more than 39 K, the thin film layer has conductivity and thus is difficult to function as an insulation layer. Based thereon, the thin film according to the present inventive concept may be implemented so that the thin film layer is formed to have a thickness of 40 Å to 70 Å and is crystallized to have a dielectric constant of 20 K to 30 K.

The thin film layer may be formed of a mixed material including at least one of hafnium and zirconium. The thin film layer may be formed of a mixed material including at least one of hafnium, zirconium, and aluminum. The thin film layer may be deposited on the substrate S through the adsorption step S10 and the deposition step S20 and may be crystallized through the crystallization step S30.

The thin film layer may be partially crystallized, and thus, may be formed to have a thickness of 40 Å to 70 Å and may be formed to have a dielectric constant of 20 K to 30 K. In this case, comparing with all of the thin film layer is crystallized, the thin film according to the present inventive concept may be implemented to have a dielectric constant and a thickness sufficient to be used as the insulation layer 210 and reduce a process time, thereby increasing productivity.

Furthermore, a dielectric constant of the thin film layer may be determined based on the following Equation 1.

$$Cox \times ( \frac{D}{A} ) \qquad [ Equation 1 ]$$

In the Equation 1, Cox may be an oxide capacitance of the thin film layer, D may be a thickness of the thin film layer, and A may be an area of the thin film layer. The dielectric constant of the thin film layer calculated through the Equation 1 may be implemented to 20 K to 30 K.

The thin film layer may be formed to have an equivalent oxide thickness (EOT) of 6.5 Å to 9.7 Å. EOT represents a certain degree to which a high-k dielectric material shows a thickness effect, compared to silicon dioxide (SiO₂). That is, EOT denotes a thickness of the high-k dielectric material when having the same capacitance as that of to silicon dioxide (SiO₂). When EOT of the thin film layer is less than 6.5 Å, the leakage of a current increases, and when EOT of the thin film layer is more than 9.7 Å, it is difficult to miniaturize a thickness of the thin film layer. Based thereon, the thin film layer may be formed to have EOT of 6.5 Å to 9.7 Å, and thus, may be formed to have a thin thickness and may be implemented to decrease the leakage of a current.

The thin film layer may be formed of a high-k dielectric material and may be crystallized by using plasma. When plasma energy is transferred into the thin film by using plasma, impurities are removed while crystallization is being performed in the thin film, and only a crystal having a high bonding force may remain as a crystal having a low bonding force is de-bonded. Accordingly, the thin film according to the present inventive concept may have more enhanced quality through film densification, crystallization, and impurity removal. The thin film layer may be formed by crystallizing a high-k dielectric material by using plasma in an ultra-high vacuum state.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A method of manufacturing a thin film, the method comprising:
an adsorption step of injecting a source gas including a high-k dielectric material to adsorb the high-k dielectric material onto a substrate;
a deposition step of injecting a reactant gas reacting on the source gas to deposit a thin film including the high-k dielectric material on the substrate; and
a crystallization step of crystallizing the high-k dielectric material by using plasma.

2. The method of claim 1, wherein the crystallization step is performed after the deposition step is performed.

3. The method of claim 1, wherein the crystallization step and the deposition step are performed together.

4. The method of claim 1, wherein the crystallization step comprises:
a first crystallization step performed along with the deposition step; and
a second crystallization step performed after the deposition step and the first crystallization step are performed.

5. The method of claim 1, wherein the adsorption step injects a mixed gas, including at least one of hafnium (Hf) and zirconium (Zr), onto the substrate.

6. The method of claim 1, wherein the crystallization step generates plasma by using a plasma gas including at least one of helium (He), argon (Ar), and ammonia (NH3).

7. The method of claim 6, wherein the deposition step injects ozone (O3) as a reactant gas onto the substrate.

8. The method of claim 1, comprising:
a first purge step of injecting a purge gas onto the substrate after the adsorption step is performed; and
a second purge step of injecting the purge gas onto the substrate after the deposition step is performed.

9. A thin film comprising:
a thin film layer formed on a substrate by using a mixed material including a high-k dielectric material,
wherein the thin film layer is formed to have a thickness of 40 Å to 70 Å and is crystallized to have a dielectric constant of 20 K to 30 K.

10. The thin film of claim 9, wherein the thin film layer is formed of a mixed material including at least one of hafnium (Hf) and zirconium (Zr).

11. The thin film of claim 9, wherein the thin film layer is partially crystallized and is formed to have a thickness of 40 Å to 70 Å and a dielectric constant of 20 K to 30 K.

12. The thin film of claim 9, wherein the dielectric constant of the thin film layer is determined based on the following Equation,
$$Cox \times ( \frac{D}{A} )$$
Cox is an oxide capacitance of the thin film layer, D is the thickness of the thin film layer, and A is an area of the thin film layer.

13. The thin film of claim 9, wherein the thin film layer is formed to have an equivalent oxide thickness (EOT) of 6.5 Å to 9.7 Å.

14. The method of claim 2, comprising:
a first purge step of injecting a purge gas onto the substrate after the adsorption step is performed; and
a second purge step of injecting the purge gas onto the substrate after the deposition step is performed.

15. The method of claim 3, comprising:
a first purge step of injecting a purge gas onto the substrate after the adsorption step is performed; and
a second purge step of injecting the purge gas onto the substrate after the deposition step is performed.

16. The method of claim 4, comprising:
a first purge step of injecting a purge gas onto the substrate after the adsorption step is performed; and
a second purge step of injecting the purge gas onto the substrate after the deposition step is performed.

17. The method of claim 5, comprising:
a first purge step of injecting a purge gas onto the substrate after the adsorption step is performed; and
a second purge step of injecting the purge gas onto the substrate after the deposition step is performed.

18. The method of claim 6, comprising:
a first purge step of injecting a purge gas onto the substrate after the adsorption step is performed; and
a second purge step of injecting the purge gas onto the substrate after the deposition step is performed.

19. The method of claim 7, comprising:
a first purge step of injecting a purge gas onto the substrate after the adsorption step is performed; and
a second purge step of injecting the purge gas onto the substrate after the deposition step is performed.
